(19) United States
(12) Patent Application Publication
(10) Pub. No.: US 2005/0087226 A1
(43) Pub. Date: Apr. 28, 2005

(54) Electrode arranging method

(75) Inventors: Shoji Nishida, Kanagawa (JP); Noritaka Ukiyo, Shiga (JP); Masaaki Iwane, Shiga (JP); Yukiko Iwasaki, Shiga (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/957,577

(22) Filed: Oct. 5, 2004

(30) Foreign Application Priority Data
Oct. 28, 2003 (JP) 2003-366967

(51) Int. Cl. H01L 31/00

(52) U.S. Cl. 136/256

(57) ABSTRACT

The method of arranging an electrode according to the present invention includes: arranging an electrode material (103) for forming a eutectic with silicon on a silicon base (101) having unevenness; heating the silicon base (101) at a temperature equal to or higher than a eutectic temperature of the silicon and the electrode material (103); and cooling the silicon base (101) to flatten the unevenness on a surface of the silicon base just under the arranged electrode material (103). The present invention can provide a method of arranging an electrode on an uneven surface, which is a simple method and enables mass-production, and more particularly a method of arranging an electrode on a surface of a solar cell which can realize high efficiency of the solar cell.

### BACKGROUND OF THE INVENTION

1. Field of the Invention

The present invention relates to a method of arranging an electrode on an uneven surface, and more particularly to a method of arranging an electrode on a surface of a solar cell, which has high efficiency and enables mass-production.

2. Related Background Art

In light of improving photoelectric conversion efficiency, the surface of a crystalline solar cell generally has an uneven shape (texture). An electrode is arranged on the surface having the uneven shape. In general, in a solar cell manufacturing process, an Ag paste is formed in a comb shape (grid) by printing and then baked at a temperature of 700° C. to 800° C. At this time, when the uneven shape has unevenness substantially in the order of μm or more, the Ag paste is applied unevenly in printing. Step-like disconnection occurs in some cases. This becomes a factor for deteriorating a characteristic of the solar cell. To prevent this, there have been proposed methods of flattening a surface of the solar cell at an electrode arranging position in advance and forming an electrode on the surface (Japanese Patent Application Laid-Open Nos. H02-143467 and H05-326989).

However, it is necessary for the conventional methods to align the position of the flattened surface with an Ag paste arranging position in Ag paste printing. Therefore, a simpler electrode arranging method is required to improve the productivity.

On the other hand, according to Japanese Patent Application Laid-Open No. H10-275927, there has been disclosed a technique for melting a surface electrode and a collector at a high temperature by induction heating to mix the surface electrode with the collector and come into close contact with each other, when the collector is formed on the surface electrode.

However, according to the technique described in Japanese Patent Application Laid-Open No. H10-275927, the surface of a photoelectric conversion layer cannot be flattened.

According to Japanese Patent Application Laid-Open No. H11-312813, there has been disclosed a technique for making glass frit in an electroconductive paste and silicon eutectic to improve an adhesion therebetween.

However, according to the technique described in Japanese Patent Application Laid-Open No. H11-312813, the glass frit and the silicon cannot be completely melted for flattening.

### SUMMARY OF THE INVENTION

The present invention has been accomplished as a result of extensive studies of the inventors of the present invention to solve the problems in the above-mentioned conventional techniques. An object of the present invention is to provide a method of arranging an electrode on an uneven surface, which is simple and enables mass-production, and more particularly to a method of arranging an electrode on a surface of a solar cell, which can realize high efficiency of the solar cell.

According to an aspect of the present invention, there is provided a method of arranging electrode, including:

arranging an electrode material for forming a eutectic with silicon on a silicon base having unevenness;

heating the silicon base at a temperature equal to or higher than a eutectic temperature of the silicon and the electrode material; and

cooling the silicon base to flatten the unevenness on a surface of the silicon base just under the arranged electrode material.

According to another aspect of the present invention, there is provided a method of arranging electrode, including: arranging an electrode material for forming a eutectic with silicon on a silicon base having unevenness; selectively heating the electrode material and a part of the silicon base just under the electrode material at a temperature equal to or higher than a eutectic temperature of the silicon and the electrode material by induction heating; and cooling the electrode material and the part of the silicon base to flatten unevenness on a surface of the part of the silicon base just under the arranged electrode material.

Preferred modes of the above-described electrode arranging methods according to the present invention are given under.

The electrode material is at least one selected from the group consisting of Cu, Ag, Al, Sn, Au, and In.

The electrode material contains a dopant for the silicon.

An anti-reflection film is formed on a surface of the silicon base having the unevenness and the electrode material is arranged on the anti-reflection film.

The electrode material is arranged by printing a metallic paste and drying or baking the metallic paste.

A height of the unevenness is in a range form 1 μm to 100 μm.

### BRIEF DESCRIPTION OF THE DRAWINGS

FIGS. 1A, 1B, 1C, and 1D are schematic step views showing an example of a method of the present invention;

FIGS. 2A, 2B, 2C, and 2D are schematic step views showing another example of the method of the present invention;

FIGS. 3A, 3B, 3C, and 3D are schematic step views showing still another example of the method of the present invention;

FIGS. 4A, 4B, 4C, 4D, and 4E are schematic step views showing an example of producing a solar cell by the method of the present invention; and

FIG. 5 is an explanatory view showing a multi-blade wheel for making a polycrystalline silicon substrate surface uneven in Example 7.

### DESCRIPTION OF THE PREFERRED EMBODIMENTS

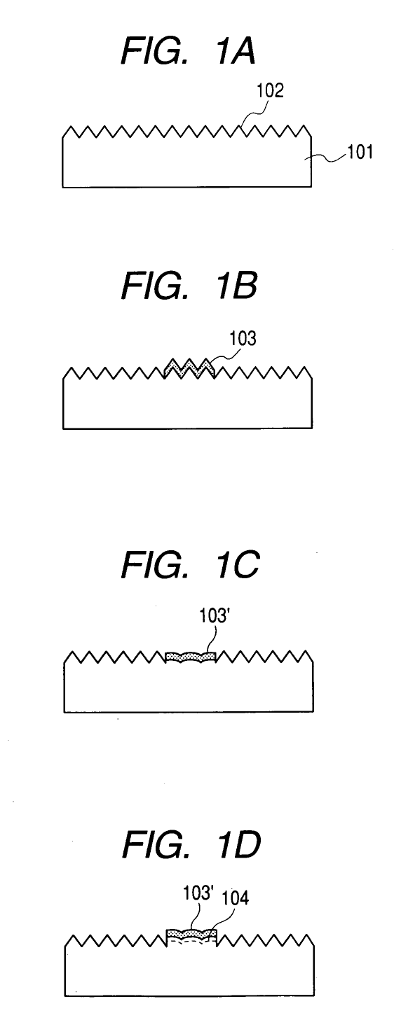

FIGS. 1A to 1D show an example of an electrode arranging method of the present invention. A silicon substrate 101 having an uneven surface 102 with a height of about 1 μm to 10 μm is prepared. A paste 103 containing a metal such as Cu, Ag, Al, Sn, Au, or In is applied onto the uneven surface 102 by screen printing, gravure printing, or the like, and then dried (FIGS. 1A and 1B) . Next, the silicon substrate 101 is placed in a furnace, a rapid heating furnace, or the like and heated at a temperature equal to or higher than a temperature at which a eutectic of the metal and silicon is formed (eutectic temperature). Therefore, the metal 103′ is melted and a part of uneven silicon substrate under the metal 103′ is melted therein, thereby flattening the uneven silicon (FIG. 1C). For example, in the case of Ag (silver), because a eutectic temperature is 830° C., it is set to a temperature equal to or higher than 830° C. and maintained for some time. After that, the silicon substrate 101 is cooled to reprecipitate an excessive amount of silicon melted in the metal 103′ on a wafer under the metal 103′ (FIG. 1D).

As described above, an electrode pattern is formed on the uneven surface by printing using a metallic paste. Then, the substrate is heated at the temperature equal to or higher than the eutectic temperature and left standing for a predetermined time. Thus, the flatness of an uneven part just under an electrode portion is accelerated, and processing such as electrode alignment after flattening is unnecessary.

According to another example of the electrode arranging method of the present invention, as in the above-mentioned example, the paste 103 containing the metal such as Cu, Ag, Al, Sn, Au, or In is applied onto the uneven surface 102 and then dried. Next, a metallic (electrode) portion and a silicon part located just under the metallic (electrode) portion are selectively heated at the temperature equal to or higher than the eutectic temperature of the metal and the silicon by induction heating, and then cooled. Even in such a case, as in the above-mentioned example, the silicon part located just under the metallic (electrode) portion can be flattened. Because an induction heating method is used, the metallic (electrode) portion and its vicinities can be selectively heated (see Japanese Patent Application Laid-Open Nos. H09-092946 and 2001-230426, or the like) . Thus, as compared with the above-mentioned example in which the entire substrate is heated, there is a merit that flattening processing can be performed for a short time, so that the productivity can be further improved.

When the electrode arranging surface in the present invention is flattened as described above, a dopant for silicon is contained in advance in a metallic (electrode) material for forming a eutectic alloy with silicon as disclosed in Japanese Patent Application Laid-Open No. 2002-511190. Therefore, a conductivity type of a flattened part (regrowth silicon layer) just under an electrode can be controlled. It is also possible to facilitate ohmic contact with the electrode.

On the other hand, there have been widely known methods of forming an electrode on a semiconductor base using an electroconductive paste or the like and then performing heat treatment to form a collector, which are disclosed in, for example, Japanese Patent Application Laid-Open Nos. H06-037340 and H03-046985. Those techniques merely provide a method of forming an electrode on a light-receiving surface side. Therefore, the techniques are different from the present invention and are not directed to flattening of the surface of silicon just under the electrode by heat treatment at the temperature equal to or higher than the eutectic temperature of the metal and the silicon.

The electrode material used in the present invention may be any material for forming a eutectic with silicon. In views of flattening the silicon surface and using the material as the electrode after flattening, an electrode material capable of melting a large amount of silicon therein when the electrode material is heated and having a low volume resistivity is selected. Then, Cu, Ag, Al, Sn, Au, In, or the like is suitably used as the electrode material. In order to use the electrode material for printing, the electrode material can be mixed with glass frit or vehicle, an organic solvent, and the like to form a metallic paste.

In the present invention, the degree of a height of unevenness on the surface of a base on which the electrode material is formed is related to a kind of an electrode material to be arranged, a thickness thereof, and the like. The height of the unevenness is preferably in a range from about 1 μm to 100 μm in consideration with a thickness of an electrode material formed by printing as described later and the amount of silicon which can be melted in the electrode material.

As means for arranging the electrode material in the present invention, a method of printing and drying or baking the metallic paste is simplest and most productive. Screen printing, gravure printing, offset printing, or the like is preferably used as a printing method. A thickness of the metallic paste applied by printing is changed according to the printing method and a pattern of an electrode to be applied. The thickness of the metallic paste can be set to approximately several μm to 20 μm in the screen printing and to approximately several μm to 200 μm in the gravure printing and the offset printing. A dopant for silicon is contained in advance in the metallic paste. Therefore, a conductivity type of a flattened part (regrowth silicon layer) just under the electrode can be controlled. It is possible to facilitate ohmic contact with the electrode.

In the present invention, as the induction heating means for selectively heating the metallic material and the silicon part located just under the metallic material at the temperature equal to or higher than the eutectic temperature of the silicon and the electrode material, an apparatus composed of a heating coil and a high frequency power source is simple and preferably used. The heating coil is a winding made of a conductor (mainly copper) pipe. An object to be heated, which is made of a metal or a low resistance material is placed in the heating coil and a high frequency current is allowed to flow into the heating coil. Therefore, an eddy current flows into the object to be heated to increase a temperature thereof by Joule heat. This is a principle of induction heating. With respect to the feature of such an apparatus, rapid heating and local heating are possible and a running cost is low. The high frequency power source used in the present invention is determined as appropriate according to a kind of the electrode material which is the object to be heated and a thickness thereof, the number of substrates to be processed, and the like. A frequency of the high frequency power source is within a range of several kHz to 1000 kHz and an output thereof is within a range of several tens W to 10 kW. Preferably, the frequency may be set to 10 kHz to 800 kHz and the output may be set to 100 W to 10 kW.

In the present invention, an anti-reflection film is formed in advance on the surface of the silicon base having unevenness. The electrode material is arranged on the anti-reflection film and heated at the temperature equal to or higher than the eutectic temperature of the metal as the electrode material and the silicon, so that the metal penetrates the anti-reflection film, whereby flattening can be performed. A so-called fire through occurs while a temperature is increased by heating, with the result that flattening and electrode conduction are caused in a self-alignment fashion. Thus, the steps for producing a solar cell can be simplified.

Hereinafter, desired flattening which is effected by a method of the present invention will be described in more detail based on the following examples. The present invention is not limited by those examples.

### (EXAMPLE 1)

In this example, an uneven surface is flattened by a method as shown in FIGS. 1A to 1D. First, a surface of a single-crystalline silicon substrate (p-type, plane orientation (100)) 101 was etched at a temperature of 80° C. to 90° C. by anisotropic etching using a 2% KOH aqueous solution to form a texture surface 102 having unevenness with a height of about 1 μm to 10 μm (FIG. 1A). Then, POCl₃ as a diffusion source was used for the texture surface of the substrate. Thermal diffusion of P was performed on the texture surface at a temperature of 830° C. to form an n⁺ layer (not shown). After the n⁺ layer formed on the rear surface was removed by etching, a copper paste with a thickness of 20 μm was applied onto the texture surface by screen printing and dried to form a pattern of the surface electrode 103, as shown in FIG. 1B. Next, the substrate was placed in a furnace (not shown) and maintained at 800° C. for 60 minutes. Thus, the silicon was sufficiently melted in the copper electrode 103′, so that an uneven part under the copper electrode 103′ was flattened (FIG. 1C). After that, a temperature was gradually reduced (temperature falling rate: −3° C./minute) to precipitate the silicon melted in the copper electrode on a flattened surface, thereby forming a silicon layer 104 (FIG. 1D). At this time, the unevenness on the surface of the reprecipitated silicon layer 104 was flattened to a height of about 0.2 μm to 1 μm.

### (EXAMPLE 2)

In this example, flattening on an uneven surface and doping into a regrowth layer are performed by the method as shown in FIGS. 1A to 1D. First, a surface of a single-crystalline silicon substrate (p-type, plane orientation (100)) 101 was etched at a temperature of 80° C. to 90° C. by anisotropic etching using a 2% KOH aqueous solution to form the texture surface 102 having unevenness with a height of about 1 μm to 10 μm (FIG. 1A). Thermal diffusion of P was performed on the texture surface of the substrate at a temperature of 830° C. using POC1₃ as a diffusion source to form an n⁺ layer (not shown). The n⁺ layer formed on a rear surface of the substrate was removed by etching. Then, as shown in FIG. 1B, a copper paste containing P atoms as dopants and having a thickness of 40 μm was applied onto the texture surface by gravure printing and dried to form a pattern of the surface electrode 103. Next, the substrate was placed in a furnace (not shown) and maintained at 800° C. for 60 minutes. Therefore, the silicon was sufficiently melted in the copper electrode, so that an uneven part under the copper electrode was flattened (FIG. 1C). After that, a temperature was gradually reduced (temperature falling rate: −3° C./minute) to precipitate the silicon melted in the copper electrode on a flattened surface, thereby forming the silicon layer 104 (FIG. 1D). At this time, the P atoms contained in the copper electrode intruded in the silicon layer 104 formed by reprecipitation, thereby performing doping. Thus, an emitter layer (n⁺) having a suitable concentration was formed just under the copper electrode. The unevenness on the surface of the reprecipitated silicon layer was flattened to a height of about 0.2 μm to 1 μm.

### (EXAMPLE 3)

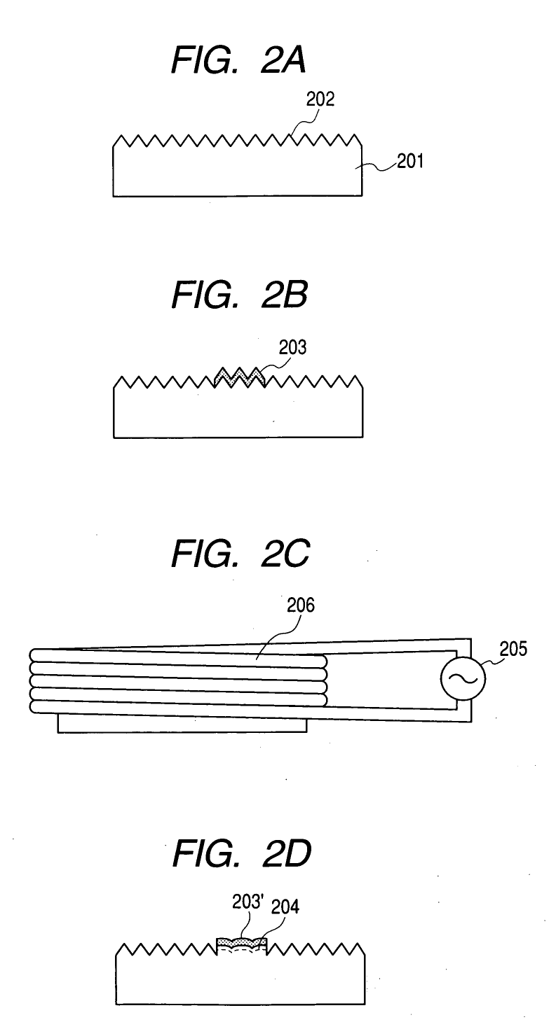

In this example, flattening on an uneven surface is performed by the method as shown in FIGS. 2A to 2D. First, a surface of a single-crystalline silicon substrate (p-type, plane orientation (100)) 201 was etched at a temperature of 80° C. to 90° C. by anisotropic etching using a 2% KOH aqueous solution to form a texture surface 202 having unevenness with a height of about 1 μm to 10 μm (FIG. 2A). Thermal diffusion of P was performed on the texture surface of the substrate at a temperature of 860° C. by applying a diffusing agent containing P₂O₅ to form an n⁺ layer (not shown). The diffusing agent applied onto the surface was removed by etching. Then, as shown in FIG. 2B, a silver paste with a thickness of 20 μm was applied onto the texture surface by screen printing and dried to form a pattern of a surface electrode 203. Next, the substrate was placed in a high frequency induction heating coil 206 and a high frequency current was caused to flow in the high frequency induction heating coil 206 at 350 kHz and 1 kW by using a high frequency power source 205. Thus, the silver electrode and its vicinities were selectively heated at about 860° C. for 10 minutes. Therefore, the silicon was sufficiently melted in the silver electrode, so that an uneven part under the silver electrode was flattened (FIG. 2C). After that, a temperature was gradually reduced (temperature falling rate: −2.5° C./minute) to precipitate the silicon melted in the silver electrode on a flattened surface, thereby forming the silicon layer 204 (FIG. 2D). At this time, the unevenness on the surface of the reprecipitated silicon layer 204 was flattened to a height of about 0.2 μm to 1 μm.

### (EXAMPLE 4)

In this example, flattening on an uneven surface and doping into a regrowth layer are performed by the method as shown in FIGS. 2A to 2D. First, a surface of the single-crystalline silicon substrate (p-type, plane orientation (100)) 201 was etched at a temperature of 80° C. to 90° C. by anisotropic etching using a 2% KOH aqueous solution to form the texture surface 202 having unevenness with a height of about 1 μm to 10 μm (FIG. 2A). Thermal diffusion of P was performed on the texture surface of the substrate at a temperature of 860° C. by applying a diffusing agent containing P₂O₅ to form an n⁺ layer (not shown). The diffusing agent applied onto the substrate surface was removed by etching. Then, as shown in FIG. 2B, a silver paste containing P atoms as dopants and having a thickness of 40 μm was applied onto the texture surface by gravure printing, dried, and baked in an infrared (IR) heating furnace at 700° C. for 2 minutes to form a pattern of the surface electrode 203. Next, the substrate was placed in the high frequency induction heating coil 206 and a high frequency current was caused to flow in the high frequency induction heating coil 206 at 350 kHz and 1 kW by using the high frequency power source 205. Thus, the silver electrode and its vicinities were selectively heated at 860° C. for 10 minutes. Therefore, the silicon was sufficiently melted in the silver electrode, so that an uneven part under the silver electrode was flattened (FIG. 2C). After that, a temperature was gradually reduced (temperature falling rate: −2.5° C./minute) to precipitate the silicon melted in the silver electrode on a flattened surface, thereby forming the silicon layer 204 (FIG. 2D). At this time, the P atoms contained in the silver electrode intruded in the silicon layer 204 formed by reprecipitation, thereby performing doping. Thus, an emitter layer (n⁺) having a suitable concentration was formed just under the silver electrode. The unevenness on the surface of the reprecipitated silicon layer was flattened to a height of about 0.3 μm to 2 μm.

### (EXAMPLE 5)

In this example, flattening on an uneven surface and doping into a regrowth layer are performed by the method as shown in FIGS. 1A to 1D. First, a surface of the single-crystalline silicon substrate (p-type, plane orientation (100)) 101 was etched at a temperature of 80° C. to 90° C. by anisotropic etching using a 1% NaOH aqueous solution to form the texture surface 102 having unevenness with a height of about 3 μm to 20 μm (FIG. 1A). Thermal diffusion of P was performed on the texture surface of the substrate at a temperature of 920° C. using POCl₃ as a diffusion source to form an n⁺ layer (not shown). The n⁺ layer formed on a rear surface of the substrate was removed by etching. Then, as shown in FIG. 1B, a tin paste containing P atoms as dopants and having a thickness of 40 μm was applied onto the texture surface by gravure printing and dried to form a pattern of the surface electrode 103. Next, the substrate was placed in a furnace (not shown) and maintained at 900° C. for 40 minutes. Therefore, the silicon was sufficiently melted in the tin electrode, so that an uneven part under the tin electrode was flattened (FIG. 1C). After that, a temperature was gradually reduced (temperature falling rate: −3° C./minute) to precipitate the silicon melted in the tin electrode on a flattened surface, thereby forming the silicon layer 104 (FIG. 1D) . At this time, the P atoms contained in the tin electrode intruded in the silicon layer 104 formed by reprecipitation, thereby performing doping. Thus, an emitter layer (n⁺) having a suitable concentration was formed just under the tin electrode. The unevenness on the surface of the reprecipitated silicon layer was flattened to a height of about 0.2 μm to 1 μm.

Examples 1 to 5 in which the unevenness on the silicon surface is flattened using copper, silver, or tin as the electrode material are described. Even when gold, indium, aluminum, or the like is used as the electrode material, flattening can be performed as in the above-mentioned examples.

### (EXAMPLE 6)

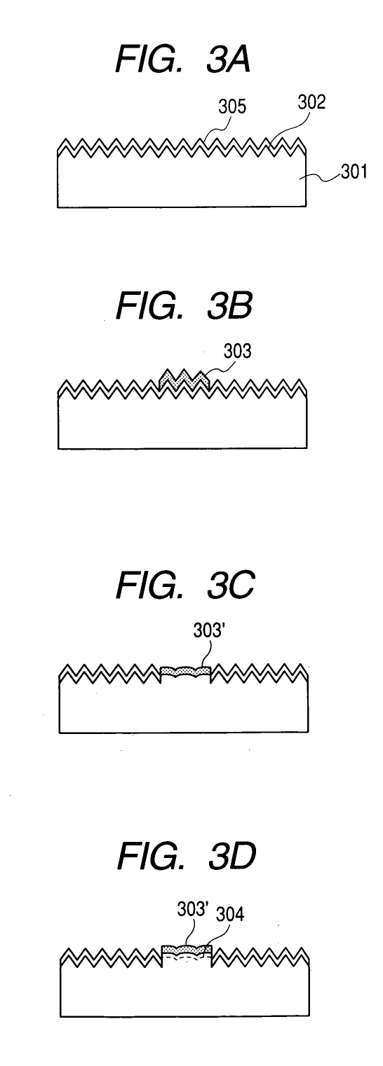

In this example, an uneven surface on which a surface anti-reflection film is provided is flattened by the method as shown in FIGS. 3A to 3D. First, a surface of a single-crystalline silicon substrate (p-type, plane orientation (100)) 301 was etched at a temperature of 80° C. to 90° C. by anisotropic etching using a 2% KOH aqueous solution to form a texture surface 302 having unevenness with a height of about 1 μm to 10 μm. Then, a diffusing agent containing P₂O₅ was applied onto the texture surface of the substrate. Thermal diffusion of P was performed on the texture surface at a temperature of 860° C. to form an n⁺ layer (not shown). After the completion of the diffusion, the diffusing agent on the texture surface was removed by etching. Then, an anti-reflection layer 305 of amorphous SiN with a thickness of 81 nm was deposited on the texture surface by a CVD apparatus using a mixture gas of SiH₄ and NH₃ (FIG. 3A). As shown in FIG. 3B, a silver paste with a thickness of 20 μm was applied onto the anti-reflection layer 305 by screen printing and dried to form a pattern of the surface electrode 203. Next, the substrate was placed in a furnace (not shown) and maintained at 860° C. for 30 minutes. At this time, the silver paste was baked, so that silver particles penetrated the SiN film and came into contact with the surface of silicon just under the SiN film. Therefore, the silicon was sufficiently melted in the silver electrode, so that an uneven part under the silver electrode was flattened (FIG. 3C). After that, a temperature was gradually reduced (temperature falling rate: −1.5° C./minute) to precipitate the silicon melted in the silver electrode on a flattened surface, thereby forming the silicon layer 204 (FIG. 3D). At this time, the unevenness on the surface of the reprecipitated silicon layer 204 was flattened to a height of about 0.2 μm to 2 μm.

According to the example described above, after the silver paste is applied and dried, the substrate is placed in the furnace and heated, so that the silver particles penetrated the SiN film. According to another example, the following can be also performed. After the silver paste is applied and dried, the substrate is baked in an infrared (IR) heating furnace at a temperature of 700° C. to 800° C. such that the silver particles penetrated the SiN film in advance. Then, the substrate is placed in the furnace.

### (EXAMPLE 7)

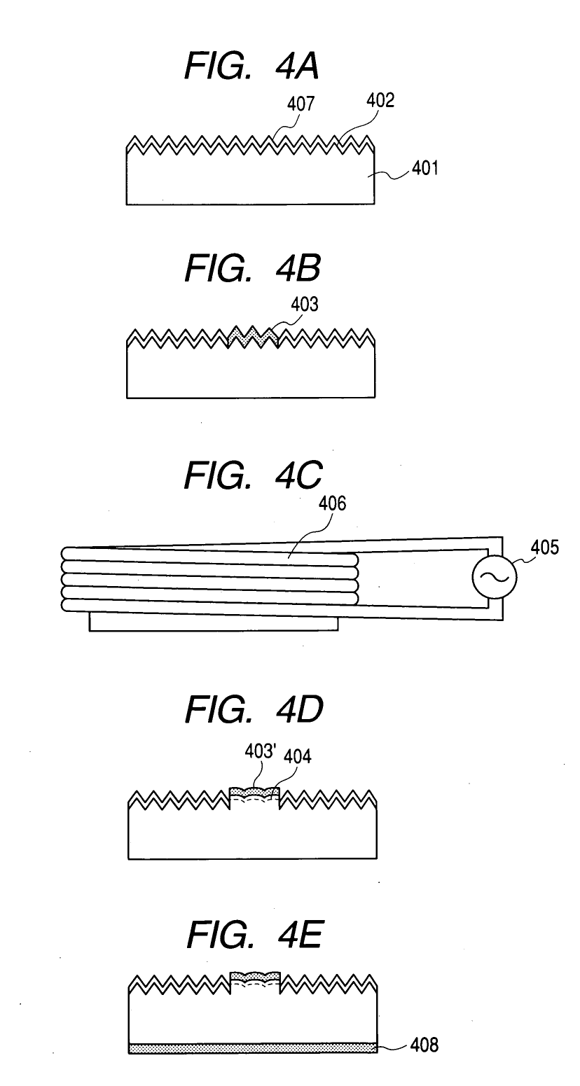

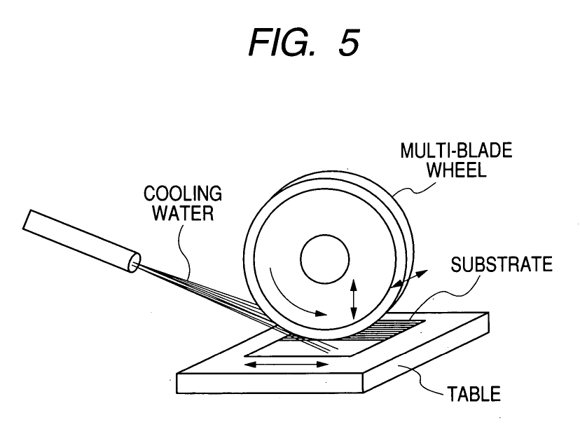

In this example, an uneven surface on which a surface anti-reflection film is provided is flattened by the method as shown in FIGS. 4A to 4E to produce an n+/p-type polycrystalline solar cell. First, unevennesses having V-shaped grooves with a depth and pitch of 30 μm were mechanically formed on a surface of a polycrystalline silicon substrate (p-type, resistivity of 0.8 Ω·cm) 401 using a multi-blade wheel as shown in FIG. 5. A damaged surface layer was removed by etching using acid. Then, a diffusing agent containing P₂O₅ was applied onto the surface of the substrate having the unevenness formed thereon and thermal diffusion of P was performed at a temperature of 860° C. to form an n⁺ layer (not shown). After the completion of the diffusion, the diffusing agent on the surface was removed by etching. Then, an anti-reflection layer 407 of amorphous SiN with a thickness of 81 nm was deposited on the uneven surface by a CVD apparatus using a mixture gas of SiH₄ and NH₃ (FIG. 4A). As shown in FIG. 4B, a silver paste containing P atoms as dopants and having a thickness of 40 μm was applied onto the anti-reflection layer 407 by gravure printing and dried. The substrate was baked in an infrared (IR) heating furnace at 780° C. for 2 minutes, so that a pattern of a surface electrode 403 was formed and silver particles penetrated the SiN film. Next, the substrate was placed in a high frequency induction heating coil 406. A high frequency current was allowed to flow into the high frequency induction heating coil 406 at 450 kHz and 1.5 kW by a high frequency power source 405. A silver electrode and its vicinities were selectively heated at about 880° C. for 15 minutes. Therefore, the silicon was sufficiently melted in the silver electrode, so that an uneven part under the silver electrode was flattened (FIG. 4C) . After that, a temperature was gradually reduced (temperature falling rate: −2.5° C./minute) . to precipitate the silicon melted in the silver electrode on a flattened surface, thereby forming a silicon layer 404 (FIG. 4D). At this time, the P atoms contained in the silver electrode intruded in the silicon layer 404 formed by reprecipitation, thereby performing doping. Thus, an emitter layer (n⁺) having a suitable concentration was formed just under the silver electrode. The unevenness on the surface of the reprecipitated silicon layer was flattened to a height of about 0.8 μm to 5 μm.

Finally, an Al paste with a thickness of 20 μm was printed on a back surface of the polycrystalline silicon substrate and dried. Then, the substrate was baked in the infrared (IR) heating furnace at 750° C. for 2 minutes to form a back electrode 408, thereby producing a polycrystalline silicon solar cell (FIG. 4E).

An I-V characteristic of the polycrystalline silicon solar cell obtained by the above-mentioned process was measured under light irradiation of AM1.5 (100 mW/cm²). As a result, an open circuit voltage of 0.59 V, a short circuit photo-current of 33 mA/cm², a fill factor of 0.76 and an energy conversion efficiency of 14.8% were obtained from a cell area of 4 cm².

For comparison, a solar cell was produced without flattening the uneven part by the high frequency induction heating in the above-mentioned solar cell producing method. That is, the silver paste containing P atoms as dopants and having a thickness of 40 μm was applied onto the uneven surface of the SiN film by gravure printing and dried. The substrate was baked in the infrared (IR) heating furnace at 780° C. for 2 minutes, so that the pattern of the surface electrode was formed and the silver particles penetrated the SiN film. The Al paste with a thickness of 20 μm was printed on the back surface of the substrate and dried. Then, the substrate was baked in the infrared (IR) heating furnace at 750° C. for 2 minutes to form the back electrode, thereby producing the solar cell. An I-V characteristic of the produced solar cell was examined in the same manner. As a result, an open circuit voltage of 0.58 V, a short circuit photo-current of 33 mA/cm², a fill factor of 0.72 and an energy conversion efficiency of 13.8% were obtained from a cell area of 4 cm². Thus, when the uneven part is flattened, an adhesion between the surface electrode and the silicon located just under the surface electrode is improved, thereby increasing the fill factor.

As described above, according to preferred examples of the present invention, when the electrode pattern is formed on the uneven surface by printing using the metallic paste and heated at the temperature equal to or higher than the eutectic temperature, the flatness of the uneven part just under the electrode portion is improved and processing such as electrode alignment after flattening becomes unnecessary. Therefore, the present invention is suitable for a solar cell mass production method because a simple electrode-arranging method can be provided as compared with a conventional method. Particularly, in the present invention, the metallic (electrode) portion and its vicinities can be selectively heated by using the induction heating. In this case, as compared with the case where the entire substrate is heated, the present invention has a merit that flattening processing can be performed for a short time, so that the productivity can be further improved.

This application claims priority from Japanese Patent Application No. 2003-366967 filed on Oct. 28, 2003, which is hereby incorporated by reference herein.

1. A method of arranging electrode, comprising:
arranging an electrode material for forming a eutectic with silicon on a silicon base having unevenness;
heating the silicon base at a temperature equal to or higher than a eutectic temperature of the silicon and the electrode material; and
cooling the silicon base to flatten the unevenness on a surface of the silicon base just under the arranged electrode material.

2. A method of arranging electrode according to claim 1, wherein the electrode material is at least one selected from the group consisting of Cu, Ag, Al, Sn, Au, and In.

3. A method of arranging electrode according to claim 1, wherein the electrode material contains a dopant for the silicon.

4. A method of arranging electrode according to claim 1, wherein an anti-reflection film is formed on the surface of the silicon base having the unevenness and the electrode material is arranged on the anti-reflection film.

5. A method of arranging electrode according to claim 1, wherein the electrode material is arranged by printing a metallic paste and drying or baking the metallic paste.

6. A method of arranging electrode according to claim 1, wherein a height of the unevenness is in a range from 1 μm to 100 μm.

7. A method of arranging electrode, comprising:
arranging an electrode material for forming a eutectic with silicon on a silicon base having unevenness;
selectively heating the electrode material and a part of the silicon base just under the electrode material at a temperature equal to or higher than a eutectic temperature of the silicon and the electrode material by induction heating; and
cooling the electrode material and the part of the silicon base to flatten the unevenness on a surface of the part of the silicon base just under the arranged electrode material.

8. A method of arranging electrode according to claim 7, wherein the electrode material is at least one selected from the group consisting of Cu, Ag, Al, Sn, Au, and In.

9. A method of arranging electrode according to claim 7, wherein the electrode material contains a dopant for the silicon.

10. A method of arranging electrode according to claim 7, wherein an anti-reflection film is formed on a surface of the silicon base having the unevenness and the electrode material is arranged on the anti-reflection film.

11. A method of arranging electrode according to claim 7, wherein the electrode material is arranged by printing a metallic paste and drying or baking the metallic paste.

12. A method of arranging electrode according to claim 7, wherein a height of the unevenness is in a range from 1 μm to 100 μm.
